(19) United States
(12) Patent Application Publication
(10) Pub. No.: US 2023/0044084 A1
(43) Pub. Date: Feb. 9, 2023

(54) Combined dual-conductive key switch

(71) Applicants: Dongguan City Kaihua Electronics Co., Ltd, Dongguan (CN); MECHANICAL KEYBOARDS, LLC, CHANDLER, AZ (US)

(72) Inventors: Joel Tubre, Phoenix, AZ (US); FuXi Wu, Dongguan (CN)

(73) Assignee: MECHANICAL KEYBOARDS, LLC, CHANDLER, AZ (US)

(21) Appl. No.: 17/397,925

(22) Filed: Aug. 9, 2021

(51) Int. Cl. H01H 13/14; H01H 13/04; H01H 13/10; H01H 13/64; H01H 13/50; G01R 33/07

(52) U.S. Cl. CPC H01H 13/14; G01R 33/07; H01H 13/04; H01H 13/10; H01H 13/64; H01H 13/503

(57) ABSTRACT

The utility model discloses a combined dual-conductive key switch comprising a base, a cover arranged above the base and a conductive core, wherein it further comprises a light-conducting component and an inductive switch which are electrically connected to a PCB respectively; and a light-blocking protrusion corresponding to the light-conducting component and a magnet corresponding to the inductive switch are respectively arranged on the conductive core; and the light-blocking protrusion triggers a conduction stroke of conducting the light-conducting component, which is different from a conduction stroke of conducting the inductive switch triggered by the magnet. According to the utility model, the combined dual-conductive key switch is provided for achieving dual-conductive functions of pressing once and performing two actions for a product, which gives more functions to the key switch and provides better user experience.

### TECHNICAL FIELD

The utility model relates to a key switch, in particular to a combined dual-conductive key switch.

### BACKGROUND ART

At present, when a key switch on the market is pressed once, the key switch is only conductive once, that is, the key switch only has a single conduction function. Along with the wide application of the key switch, not only the key switch is continuously improved for its performance requirement, but also the function requirement to the key switch is higher and higher.

For example, it is required that the key switch can be conductive twice when the key switch is pressed once. When it is applied to games, the key switch with the function of being pressed once and conductive twice has higher speed and provides better user experience for players compared with the traditional key switch.

However, the key switches with the function of being pressed once and conductive twice have not been available on the market today.

### SUMMARY OF THE UTILITY MODEL

For the defects above, the purpose of the utility model is to provide a combined dual-conductive key switch for achieving dual-conductive functions of pressing once and performing two actions for a product, which gives more functions to the key switch and provides better user experience.

The technical solution adopted by the utility model for achieving the above purpose is as follows.

A combined dual-conductive key switch comprises a base, a cover arranged above the base and a conductive core, wherein it further comprises a light-conducting component and an inductive switch which are electrically connected to a PCB respectively; and a light-blocking protrusion corresponding to the light-conducting component and a magnet corresponding to the inductive switch are respectively arranged on the conductive core; and the light-blocking protrusion triggers a conduction stroke of conducting the light-conducting component, which is different from a conduction stroke of conducting the inductive switch triggered by the magnet.

As a further improvement of the utility model, the distance between the light-blocking protrusion and the light-conducting component is not equal to a height of the magnet from a highest point of the induction distance between the magnet and the inductive switch.

As a further improvement of the utility model, the distance between the light-blocking protrusion and the light-conducting component is less than the height of the magnet from the highest point of the induction distance between the magnet and the inductive switch.

As a further improvement of the utility model, the distance between the light-blocking protrusion and the light-conducting component is greater than the height of the magnet from the highest point of the induction distance between the magnet and the inductive switch.

As a further improvement of the present utility model, the light-conducting component comprises a light emission element and a light reception element.

As a further improvement of the utility model, a first abdicating opening for the light-blocking protrusion to move up and down is formed on the base.

As a further improvement of the utility model, the inductive switch is one of a magnetic inductor and a Hall element.

As a further improvement of the utility model, a protruded mounting portion into which the magnet is inserted is protruded outward from a side edge of the conductive core.

As a further improvement of the utility model, a second abdicating opening for the protruded mounting portion to move up and down is formed on the base, and the inductive switch is provided on an outer side edge of the second abdicating opening.

The utility model has the following beneficial effects. In a single key switch, the light-conducting component and the inductive switch are additionally arranged. When the conduction stroke of conducting the light-conducting component triggered by the light-blocking protrusion is set, and is different from the conduction stroke of conducting the inductive switch triggered by the magnet, two groups of conduction components are triggered to conduct in sequence by pressing the conductive core downwards, thereby achieving dual-conductive functions of pressing once and performing two actions for a product, which gives more functions to the key switch and provides better user experience.

The above mentioned is an overview of the technical scheme of the utility model. The following is a further explanation of the utility model in combination with the attached drawings and specific implementations.

### BRIEF DESCRIPTION OF THE DRAWINGS

FIG. 1 is an exploded view of the utility model;

FIG. 2 is a schematic view of the external structure of the utility model;

FIG. 3 is a sectional view of the utility model;

FIG. 4 is a schematic view of a part of the structure of the utility model;

FIG. 5 is a schematic view of another part of the structure of the utility model;

FIG. 6 is a schematic view of yet another part of the structure of the utility model;

FIG. 7 is a structural view showing that a distance d1 between a light-blocking protrusion and a light-conducting component is less than a height d2 of a magnet from a highest point of an induction distance d0 between the magnet and an inductive switch in the utility model;

FIG. 8 is a schematic view showing the structure in which the light-conducting component is conducted earlier when the distance d1 between the light-blocking protrusion and the light-conducting component is less than the height d2 of the magnet from the highest point of the induction distance d0 between the magnet and the inductive switch in the utility model;

FIG. 9 is a schematic view showing a structure in which the inductive switch is conducted later when the distance d1 between the light-blocking protrusion and the light-conducting component is less than the height d2 of the magnet from the highest point of the induction distance d0 between the magnet and the inductive switch in the utility model;

FIG. 10 is a schematic view showing a structure in which the distance d1 between the light-blocking protrusion and the light-conducting component is greater than the height d2 of the magnet from the highest point of the induction distance d0 between the magnet and the inductive switch in the utility model;

FIG. 11 is a schematic view showing the structure in which the light-conducting component is conducted earlier when the distance d1 between the light-blocking protrusion and the light-conducting component is greater than the height d2 of the magnet from the highest point of the induction distance d0 between the magnet and the inductive switch in the utility model;

FIG. 12 is a schematic view showing the structure in which the inductive switch is conducted later when the distance d1 between the light-blocking protrusion and the light-conducting component is greater than the height d2 of the magnet from the highest point of the induction distance d0 between the magnet and the inductive switch in the utility model.

### DETAILED DESCRIPTION

In order to further explain the technical means and effects of the present utility model for achieving the intended purpose, the following detailed description of the embodiments of the present utility model will be made with reference to the accompanying drawings and preferred embodiments.

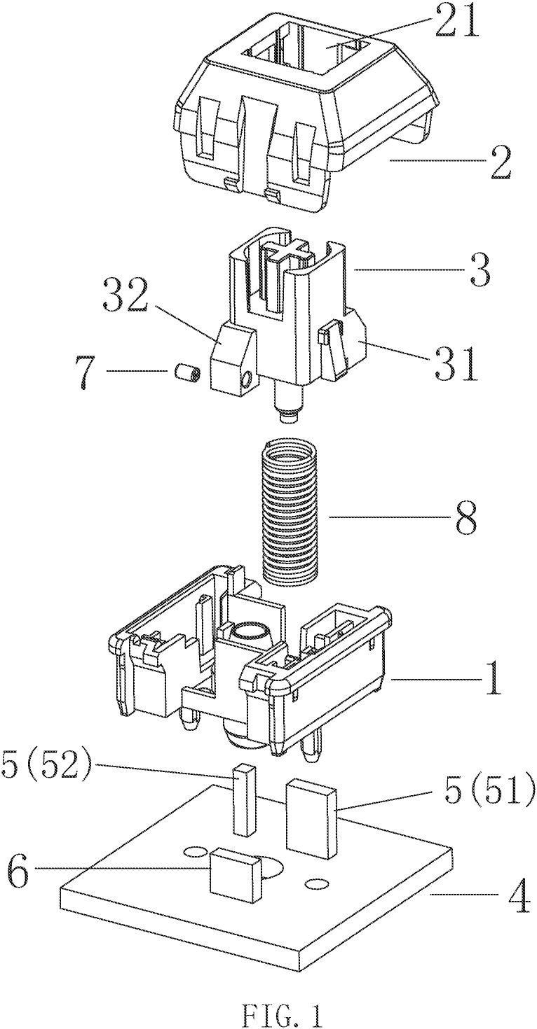

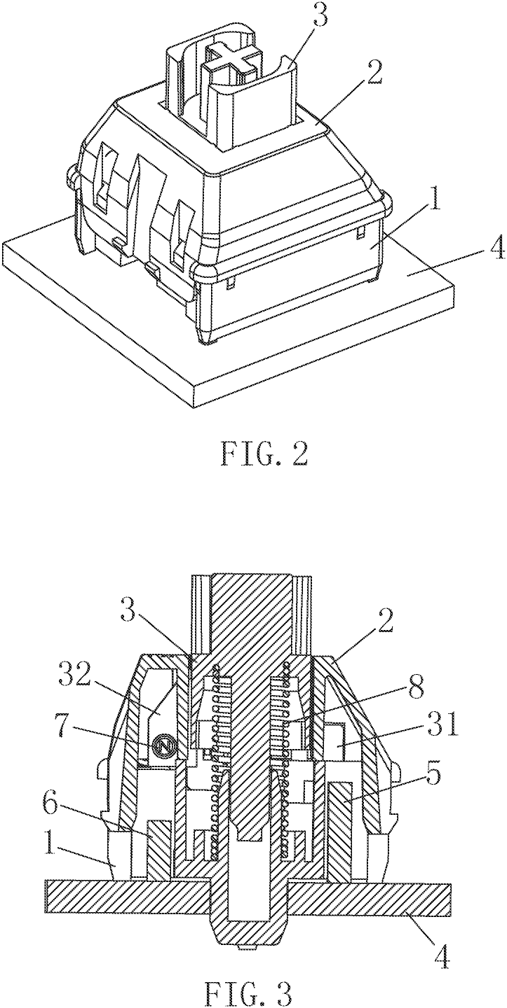

Referring to FIGS. 1 to 6, the embodiment provides a combined dual-conductive key switch comprising a base 1, a cover 2 arranged above the base 1, and a conductive core 3, wherein an opening 21 for allowing an upper part of the conductive core 3 to pass through is formed in the cover 2 so as to press the conductive core 3 downwards to trigger the conduction of the key switch. The combined dual-conductive key switch of the embodiment further comprises a light-conducting component 5 and an inductive switch 6 which are electrically connected to the PCB 4 respectively; and a light-blocking protrusion 31 corresponding to the light-conducting component 5 and a magnet 7 corresponding to the inductive switch 6 are respectively arranged on the conductive core 3; and the light-blocking protrusion 31 triggers the conduction stroke of conducting the light-conducting component 5, which is different from a conduction stroke of conducting the inductive switch 6 triggered by the magnet 7. When the conductive core 3 is pressed to move downwards, the light-blocking protrusion 31 and the magnet 7 move downwards along therewith. Due to the fact that the light-blocking protrusion 31 triggers the conduction stroke of conducting the light-conducting component 5, which is different from the conduction stroke of conducting the inductive switch 6 triggered by the magnet 7, the light-blocking protrusion 31 and the magnet 7 can trigger the conduction of the corresponding conduction component sequentially, achieving the purpose of conducting in sequence.

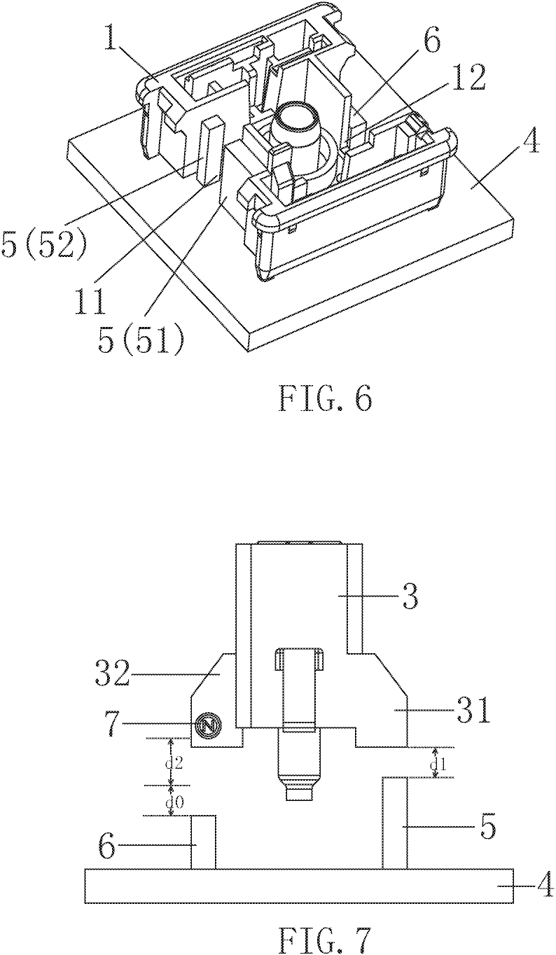

Specifically, as shown in FIGS. 1, 5 and 6, the light-conducting component 5 of the present embodiment includes a light emission element 51 and a light reception element 52. In the case where there is no structural interruption between the light emission element 51 and the light reception element 52, the light emission element 51 emits a light signal, and the light reception element 52 receives a light signal. When the structural interruption occurs between the light emission element 51 and the light reception element 52, the light reception element 52 cannot receive the light signal emitted by the light emission element 51, i.e., a signal in which the optical path is blocked occurs. In order to facilitate the upward and downward movement of the light-blocking protrusion 31, a first abdicating opening 11 for the light-blocking protrusion 31 to move up and down is formed on the base 1 in the present embodiment, as shown in FIGS. 5 and 6.

The specific working principle of the light-conducting component 5 is as follows.

In a natural state, the light-blocking protrusion 31 arranged on the conductive core 3 does not reach the light-conducting component 5, and the light reception element 52 in the light-conducting component 5 can normally receive the light signal emitted by the light emission element 51 and can be preset through a circuit on the PCB 4, in which case the light-conducting component 5 is in an off state.

When the conductive core 3 is pressed downwards, the conductive core 3 drives the light-blocking protrusion 31 to move downwards synchronously until the light-blocking protrusion 31 extends between the light emission element 51 and the light reception element 52 to block an optical path between the light emission element 51 and the light reception element 52, so that the light reception element 52 cannot receive a light signal emitted by the light emission element 51, i.e. a signal that the optical path is blocked is generated, and the light-conducting component 5 is set to be conducted.

When the pressing of the conductive core 3 is released, the conductive core 3 moves upwards and resets under the elastic restoring force of a spring 8 to drive the light-blocking protrusion 31 to move upwards. When the light-blocking protrusion 31 leaves from between the light emission element 51 and the light reception element 52, the light reception element 52 receives the light signal emitted by the light emission element 51 again, so that the light-conducting component 5 returns to an off state.

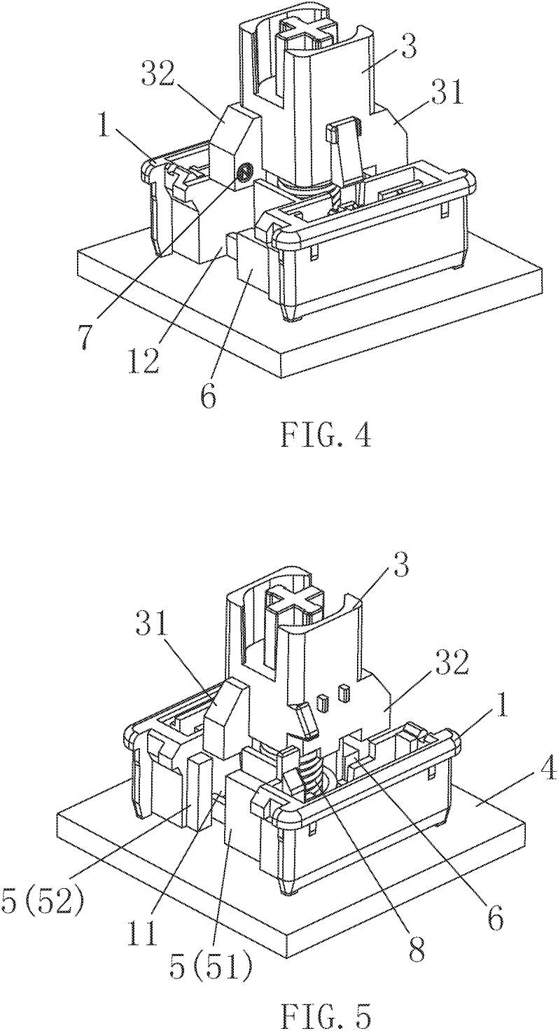

Specifically, as shown in FIGS. 1 and 4, the inductive switch 6 of the present embodiment is one of a magnetic inductor and a Hall element. When the inductive switch 6 is a magnetic inductor, the magnet 7 and the inductive switch 6 are combined to form a magnetic inductive switch. When the inductive switch 6 is a Hall element, the magnet 7 and the inductive switch 6 are combined to form a Hall inductive switch.

Specifically, the working principle of the magnetic inductive switch is as follows.

In a natural state, when the distance between the magnet 7 on the conductive core 3 and the magnetic inductor on the PCB 4 is far enough, that is, the distance between the magnet 7 and the magnetic inductor is greater than the induction distance between the both, the magnetic inductor on the PCB 4 cannot induct the magnetism of the magnet 7 on the conductive core 3, and the circuit is disconnected, that is, the magnetic inductive switch is in an off state.

When the conductive core 3 is pressed downwards, the conductive core 3 drives the magnet 7 to act downwards. When the conductive core 3 is pressed downwards to a certain stroke, and the distance between the magnet 7 and the magnetic inductor reaches the induction distance between the both, the magnetic inductor inducts the magnetism, and the circuit is conducted, that is, the magnetic inductive switch is in an on state.

When the pressing of the conductive core 3 is released, the conductive core 3 moves upwards and resets under the elastic restoring force of the spring 8 to drive the magnet 7 to move upwards. When the distance between the magnet 7 and the magnetic inductor is greater than the induction distance between the both, the magnetic inductor cannot induct the magnetism of the magnet 7, the circuit is disconnected, and the magnetic inductive switch returns to the off state.

Specifically, the working principle of the Hall inductive switch is as follows.

In a natural state, when the distance between the magnet 7 on the conductive core 3 and the Hall element on the PCB 4 is far enough, that is, the distance between the magnet 7 and the Hall element is greater than the induction distance between the magnet 7 and the Hall element, and the Hall element cannot induct the magnetism of the magnet 7 on the conductive core 3, that is, no signal is generated by the Hall element; and the circuit is disconnected, that is, the Hall inductive switch is in an off state.

When the conductive core 3 is pressed downwards, the conductive core 3 drives the magnet 7 to move downwards. When the conductive core 3 is pressed downwards to a certain stroke, and the distance between the magnet 7 and the Hall element reaches the induction distance between the both, the Hall element inducts the magnetism, that is, the Hall element generates a signal (for example, a signal of changing a resistance value, a signal of changing the voltage value and the like). Along with the increase of the magnetic force, the signal value is also increased along therewith, and linearly increased, and the electrical property is output, the circuit is conducted, namely the Hall inductive switch is in an on state.

When the pressing of the conductive core 3 is released, the conductive core 3 moves upwards and resets under the action of the elastic restoring force of the spring 8 to drive the magnet 7 to move upwards. When the distance between the magnet 7 and the Hall element is greater than the induction distance between the both, the Hall element cannot conduct the magnetism of the magnet 7, that is, no signal is generated by the Hall element, the circuit is disconnected, and the Hall inductive switch returns to the off state.

In the present embodiment, as shown in FIGS. 1, 3 and 4, for the mounting of the magnet 7, a protruded mounting portion 32 into which the magnet is inserted is protruded outward from a side edge of the conductive core 3. When the protruded mounting portion 32 moves up and down along with the conductive core 3 as a whole, the magnet 7 moves up and down along with the protruded mounting portion 32 synchronously to achieve the purpose of triggering the conduction of the inductive switch 6. Meanwhile, as shown in FIG. 4, a second abdicating opening 12 for the protruded mounting portion 32 to move up and down is formed on the base 1, and the inductive switch 6 is provided on an outer side edge of the second abdicating opening 12.

According to the structural characteristics of the light-conducting component 5 and the inductive switch 6, the conduction strokes of the light-conducting component 5 and the inductive switch 6 can be set as follows. As shown in FIG. 7, a distance d1 between the light-blocking protrusion 31 and the light-conducting component 5 is not equal to a height d2 of the magnet 7 from a highest point of an induction distance d0 between the magnet 7 and the inductive switch 6, thereby realizing different conduction strokes. In the specific structural design, the method can be realized in the following two ways.

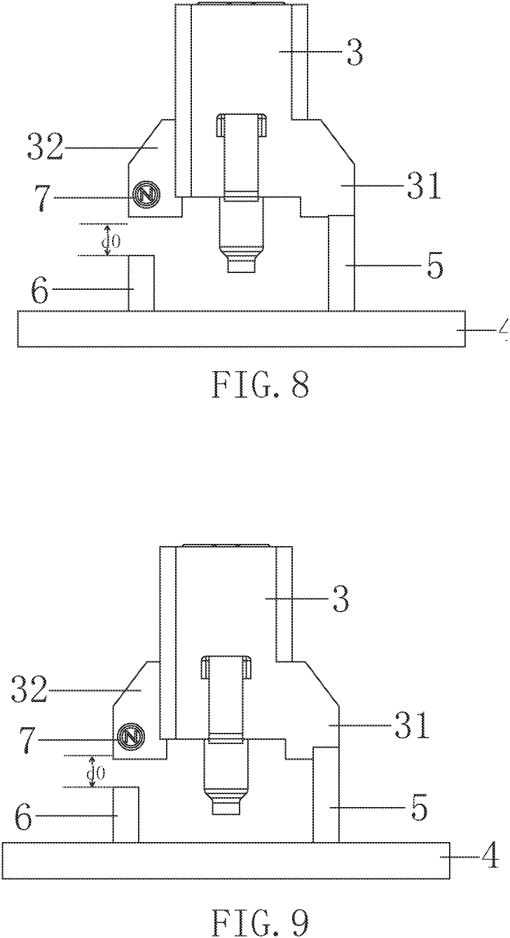

The distance d1 between the light-blocking protrusion 31 and the light-conducting component 5 is less than the height d2 of the magnet 7 from the highest point of the induction distance d0 between the magnet 7 and the inductive switch 6, as shown in FIG. 7. When the conductive core 3 is pressed to move downward, the light-blocking protrusion 31 and the magnet 7 move downward in synchronization. Since the distance d1 between the light-blocking protrusion 31 and the light-conducting component 5 is less than the height d2 of the magnet 7 from the highest point of the induction distance d0 between the magnet 7 and the inductive switch 6, the light-blocking protrusion 31 enters between the light emission element 51 and the light reception element 52 when the stroke of the downward movement of the conductive core 3 exceeds the distance d1, as shown in FIG. 8, the optical path of the light-conducting component 5 is blocked, and the light-conducting component 5 is then conducted earlier. The conductive core 3 continues to move downwards until the distance between the magnet 7 and the inductive switch 6 reaches the induction distance d0 between the magnet 7 and the inductive switch 6, as shown in FIG. 9, the inductive switch 6 inducts the magnetism, the circuit is conducted, and then the inductive switch 6 is conducted later. Therefore, the light-conducting component 5 is conducted earlier as compared to the inductive switch 6, thereby achieving the purpose of conducting in sequence.

When the pressing of the conductive core 3 is released and the conductive core 3 moves upwards and resets, the light-blocking protrusion 31 and the magnet 7 move upwards synchronously, and the distance between the magnet 7 and the inductive switch 6 is greater than the induction distance d0 between the both, the inductive switch 6 cannot induct the magnetism of the magnet 7, and the inductive switch 6 is disconnected earlier. When the conductive core 3 continues to move upwards, and the light-blocking protrusion 31 leaves the light-conducting component 5, the signal that the optical path generated by the light-conducting component 5 is blocked disappears, and then the light-conducting component 5 is disconnected. That is, the inductive switch 6 is switched off earlier than the light-conducting component 5.

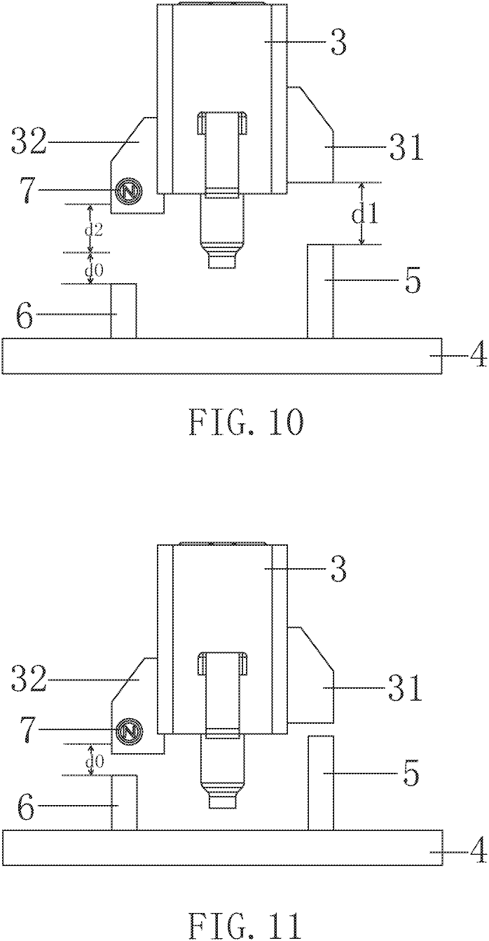

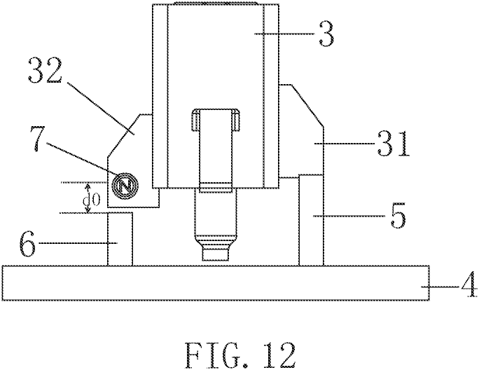

The distance d1 between the light-blocking protrusion 31 and the light-conducting component 5 is greater than the height d2 of the magnet 7 from the highest point of the induction distance d0 between the magnet 7 and the inductive switch 6, as shown in FIG. 10. When the conductive core 3 is pressed to move downward, the light-blocking protrusion 31 and the magnet 7 move downward in synchronization. Since the distance d1 between the light-blocking protrusion 31 and the light-conducting component 5 is greater than the height d2 of the magnet 7 from the highest point of the induction distance d0 between the magnet 7 and the inductive switch 6, and when the distance between the magnet 7 and the inductive switch 6 reaches the induction distance d0 between the magnet 7 and the inductive switch 6 along with the downward movement of the conductive core 3, as shown in FIG. 11, the inductive switch 6 inducts the magnetism, the circuit is conducted, and then the inductive switch 6 is conducted earlier. The conductive core 3 continues to move downwards until the downward movement stroke exceeds the distance d1, the light-blocking protrusion 31 enters between the light emission element 51 and the light reception element 52, as shown in FIG. 12, the optical path of the light-conducting component 5 is blocked, and then the light-conducting component 5 is conducted later, thereby achieving the purpose of conducting in sequence.

When the pressing of the conductive core 3 is released and the conductive core 3 is moved upwards and resets, the light-blocking protrusion 31 and the magnet 7 move upwards synchronously, the light-blocking protrusion 31 firstly leaves the light-conducting component 5, the signal that the optical path generated by the light-conducting component 5 is blocked disappears, and the light-conducting component 5 is disconnected earlier; when the conductive core 3 continues to move upwards, and the distance between the magnet 7 and the inductive switch 6 is greater than the induction distance d0 between the both, the inductive switch 6 cannot induct the magnetism of the magnet 7, and the inductive switch 6 is off later.

In the description above, only the preferred embodiments of the utility model has been described, and the technical scope of the utility model is not limited in any way. Therefore, other structures obtained by adopting the same or similar technical features as those of the above embodiments of the utility model are within the scope of the utility model.

1. A combined dual-conductive key switch comprising a base, a cover arranged above the base and a conductive core, wherein it further comprises a light-conducting component and an inductive switch which are electrically connected to a PCB respectively; and a light-blocking protrusion corresponding to the light-conducting component and a magnet corresponding to the inductive switch are respectively arranged on the conductive core; and the light-blocking protrusion triggers a conduction stroke of conducting the light-conducting component, which is different from a conduction stroke of conducting the inductive switch triggered by the magnet.

2. The combined dual-conductive key switch according to claim 1, wherein the distance between the light-blocking protrusion and the light-conducting component is not equal to a height of the magnet from a highest point of the induction distance between the magnet and the inductive switch.

3. The combined dual-conductive key switch according to claim 2, wherein the distance between the light-blocking protrusion and the light-conducting component is less than the height of the magnet from the highest point of the induction distance between the magnet and the inductive switch.

4. The combined dual-conductive key switch according to claim 2, wherein the distance between the light-blocking protrusion and the light-conducting component is greater than the height of the magnet from the highest point of the induction distance between the magnet and the inductive switch.

5. The combined dual-conductive key switch according to claim 1, wherein the light-conducting component comprises a light emission element and a light reception element.

6. The combined dual-conductive key switch according to claim 1 , wherein a first abdicating opening for the light-blocking protrusion to move up and down is formed on the base.

7. The combined dual-conductive key switch according to claim 1, wherein the inductive switch is one of a magnetic inductor and a Hall element.

8. The combined dual-conductive key switch according to claim 1 , wherein a protruded mounting portion into which the magnet is inserted is protruded outward from a side edge of the conductive core.

9. The combined dual-conductive key switch according to claim 8, wherein a second abdicating opening for the protruded mounting portion to move up and down is formed on the base, and the inductive switch is provided on an outer side edge of the second abdicating opening.
